(19) United States
(12) Patent Application Publication
(10) Pub. No.: US 2025/0351265 A1
(43) Pub. Date: Nov. 13, 2025

(54) HIGH RELIABILITY CERAMIC CIRCUIT BOARD AND METHOD FOR PRODUCING THE SAME

(71) Applicant: TONG HSING ELECTRONIC INDUSTRIES, LTD., Taoyuan City (TW)

(72) Inventors: KAI-MOU CHOU, Taoyuan City (TW); CHUN-CHIEH LIAO, Taoyuan City (TW); JHIH-WEI LAI, Taoyuan City (TW); JIAN-YU SHIH, Taoyuan City (TW)

(21) Appl. No.: 18/805,507

(22) Filed: Aug. 14, 2024

(30) Foreign Application Priority Data
May 10, 2024 (TW) 113117275

(51) Int. Cl. H05K 1/03; H05K 1/11; H05K 3/00; H05K 3/16; H05K 3/42

(52) U.S. Cl. CPC H05K 1/0306; H05K 1/115; H05K 3/0094; H05K 3/16; H05K 3/424; H05K 2201/0355; H05K 2203/0723

(57) ABSTRACT

A high reliability ceramic circuit board and method for producing the same are provided. The high reliability ceramic circuit board includes a ceramic substrate, a copper pillar structure, two printed copper layers, and two direct plated copper (DPC) structures. The ceramic substrate has a first surface and a second surface and has a through hole penetrating through the ceramic substrate. The copper pillar structure is formed in the through hole of the ceramic substrate. The two printed copper layers are respectively formed on the first surface and the second surface of the ceramic substrate, and the two printed copper layers are in contact with the copper pillar structure. The two direct plated copper (DPC) structures are respectively formed on the two printed copper layers. Each of the direct plated copper (DPC) structures includes a sputtered layer, a chemical plated copper layer, and an electroplated copper layer.

### CROSS-REFERENCE TO RELATED PATENT APPLICATION

This application claims the benefit of priority to Taiwan Patent Application No. 113117275, filed on May 10, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a ceramic circuit board and method for producing the same, and more particularly to a high reliability ceramic circuit board and method for producing the same.

### BACKGROUND OF THE DISCLOSURE

A conventional ceramic circuit board does not have good enough reliability, and accordingly, the conventional ceramic circuit board can be easily cracked after undergoing several times of temperature cycling tests.

### SUMMARY OF THE DISCLOSURE

In response to the above-referenced technical inadequacy, the present disclosure provides a high reliability ceramic circuit board and method for producing the same to effectively improve on a conventional ceramic circuit board that can be easily cracked after undergoing several times of temperature cycling tests.

In order to solve the above-mentioned problems, one of the technical aspects adopted by the present disclosure is to provide a high reliability ceramic circuit board. The high reliability ceramic circuit board includes a ceramic substrate, a copper pillar structure, two printed copper layers, and two direct plated copper (DPC) structures. The ceramic substrate has a first surface and a second surface opposite to each other and has a through hole penetrating through the ceramic substrate. The copper pillar structure is formed in the through hole of the ceramic substrate. The two printed copper layers are respectively formed on the first surface and the second surface. The two printed copper layers are in contact with the copper pillar structure. The two direct plated copper (DPC) structures are respectively formed on the two printed copper layers. Each of the two direct plated copper (DPC) structures includes a sputtered layer, a chemical plated copper layer, and an electroplated copper layer, the chemical plated copper is arranged between the sputtered layer and the electroplated copper layer, and the sputtered layer is disposed adjacent to the ceramic substrate.

In order to solve the above-mentioned problems, another one of the technical aspects adopted by the present disclosure is to provide a high reliability ceramic circuit board. The high reliability ceramic circuit board includes a ceramic substrate, a copper pillar structure, a printed copper layer, and two direct plated copper (DPC) structures. The ceramic substrate has a first surface and a second surface opposite to each other and has a through hole penetrating through the ceramic substrate. The copper pillar structure is formed in the through hole of the ceramic substrate. The printed copper layer is formed on the first surface and in contact with the copper pillar structure. The two direct plated copper (DPC) structures are respectively formed on the printed copper layer and the second surface of the ceramic substrate. Each of the two direct plated copper (DPC) structures includes a sputtered layer, a chemical plated copper layer, and an electroplated copper layer, the chemical plated copper is layer arranged between the sputtered layer and the electroplated copper layer, and the sputtered layer is disposed adjacent to the ceramic substrate.

In order to solve the above-mentioned problems, yet another one of the technical aspects adopted by the present disclosure is to provide a method for producing a high reliability ceramic circuit board. The method includes a preparing process, a copper pillar structure forming process, a printing process, and a direct plating process. The preparing process is implemented by providing a ceramic substrate having a first surface and a second surface opposite to each other and having a through hole penetrating through the ceramic substrate. The copper pillar structure forming process is implemented by forming a copper pillar structure in the through hole of the ceramic substrate. The printing process is implemented by forming two printed copper layers on the first surface and the second surface of the ceramic substrate in a printing manner. The direct plating process is implemented by forming two direct plated copper (DPC) structures on the two printed copper layers in a direct plating manner. Each of the two direct plated copper (DPC) structures includes a sputtered layer, a chemical plated copper layer, and an electroplated copper layer, the chemical plated copper layer is arranged between the sputtered layer and the electroplated copper layer, and the sputtered layer is disposed adjacent to the ceramic substrate.

Therefore, in the high reliability ceramic circuit board and method for producing the same provided by the present disclosure, by virtue of “the direct plated copper (DPC) structure being formed on the printed copper layer” and “the direct plated copper (DPC) structure including the sputtered layer, the chemical plated copper layer, and the electroplated copper layer,” the reliability of a conventional ceramic circuit board that can be easily cracked after undergoing several times of temperature cycling tests is improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a cross-sectional schematic view of a high reliability ceramic circuit board according to one embodiment of the present disclosure;

FIG. 2 is a cross-sectional schematic view of a copper pillar structure including an annular sputtered layer, an annular chemical plated copper layer, and an electroplated copper pillar of the high reliability ceramic circuit board according to one embodiment of the present disclosure;

FIG. 3 is a cross-sectional schematic view of two printed copper layers that are flush with two structures of the high reliability ceramic circuit board according to one embodiment of the present disclosure;

FIG. 4 is a cross-sectional schematic view of the two printed copper layers protruding from the two structures of the high reliability ceramic circuit board according to one embodiment of the present disclosure;

FIG. 5 is a cross-sectional schematic view of the high reliability ceramic circuit board according to another embodiment of the present disclosure; and

FIG. 6 to FIG. 9 are flowcharts of a method for producing a high reliability ceramic circuit board according to different embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [High Reliability Ceramic Circuit Board]

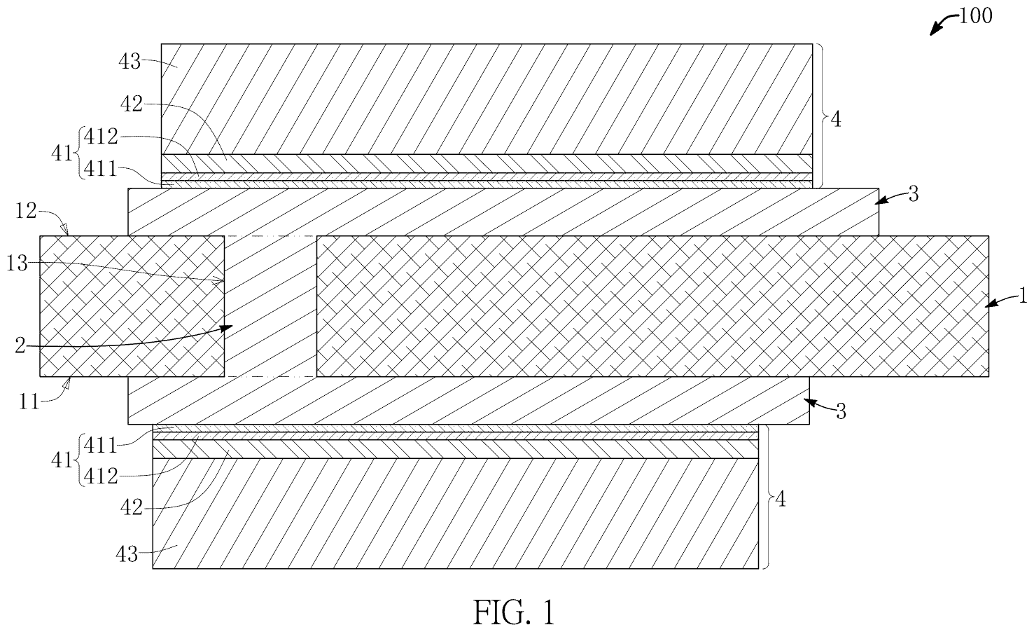

Referring to FIG. 1, FIG. 1 is a cross-sectional schematic view of a high reliability ceramic circuit board according to one embodiment of the present disclosure. One embodiment of the present disclosure provides a high reliability ceramic circuit board 100. The high reliability ceramic circuit board 100 includes a ceramic substrate 1, a copper pillar structure 2, two printed copper layers 3, and two direct plated copper (DPC) structures 4. The high reliability ceramic circuit board 100 does not crack after undergoing at least 500 times of temperature cycling tests.

The ceramic substrate 1 has a first surface 11 and a second surface 12 opposite to each other and has a through hole 13 penetrating through the ceramic substrate 1. It is worth mentioning that, as long as the through hole 13 penetrates the ceramic substrate 1, the present disclosure does not limit the formation, the dimension, the position, and the quantity of the through hole 13.

The copper pillar structure 2 is formed in the through hole 13 of the ceramic substrate 1. In one embodiment, the copper pillar structure 2 can be formed by filling copper paste in the through hole 13, but the present disclosure is not limited thereto.

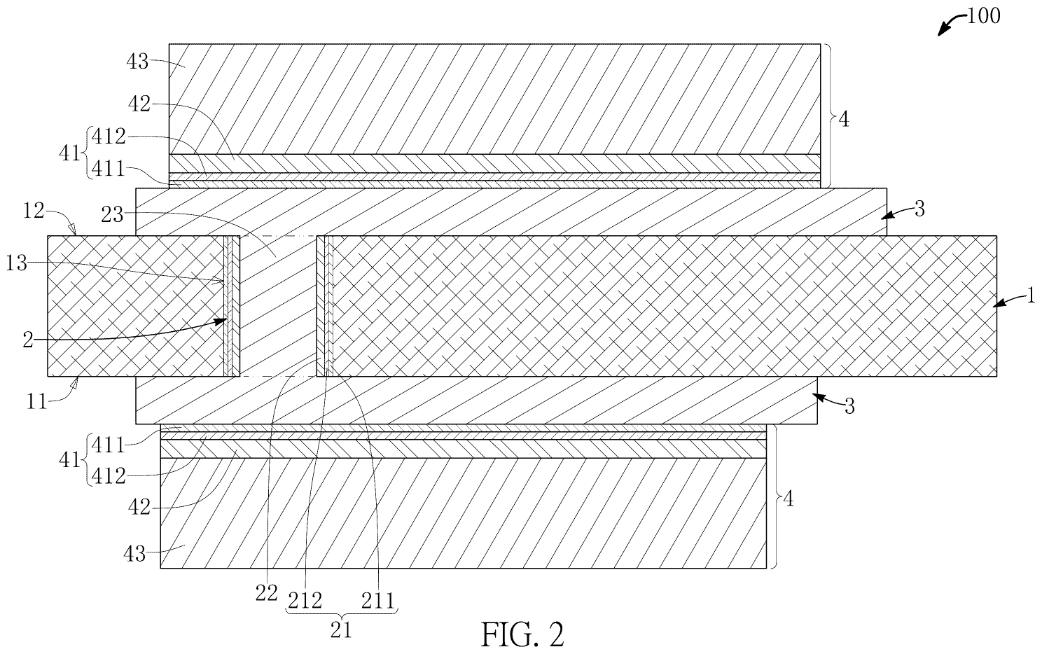

Referring to FIG. 1 and FIG. 2, FIG. 2 is a cross-sectional schematic view of a copper pillar structure including an annular sputtered layer, an annular chemical plated copper layer, and an electroplated copper pillar of the high reliability ceramic circuit board according to one embodiment of the present disclosure. In one embodiment, the copper pillar structure 2 can be formed by plating. More specifically, the copper pillar structure 2 is a direct plated copper (DPC) pillar, the copper pillar structure 2 includes an annular sputtered layer 13 in contact with a hole wall of the through hole 13, an annular chemical plated copper layer 22 arranged inside the annular sputtered layer 21, and an electroplated copper pillar 23 arranged inside the annular chemical plated copper layer 22. The direct plated copper (DPC) pillar can be formed through a direct plated copper (i.e., DPC) procedure. The annular sputtered layer 21 can further include an annular sputtered titanium layer 211 and an annular sputtered copper layer 212, the annular sputtered titanium layer 211 is in contact with the hole wall of the through hole 13, and the annular sputtered copper 212 is arranged inside the annular sputtered titanium layer 211 and in contact with the annular chemical plated copper layer 22.

The two printed copper layers 3 are respectively formed on the first surface 11 and the second surface 12, and the two printed copper layers 3 are in contact with the copper pillar structure 2. A surface of each of the printed copper layers 3 away from the ceramic substrate 1 can have a circuit pattern. It is worth mentioning that, each of the printed copper layers 3 is formed in a printing manner, and other copper layers that are formed in other manners are not suitable to be compared to the printed copper layers 3 of the present disclosure. Preferably, a thickness of each of the printed copper layers 3 can be less than 15 μm. In other words, in the high reliability ceramic circuit board 100, an overall copper thickness is mainly increased through the two direct plated copper (DPC) structures 4 but not the two printed copper layers 3.

The two direct plated copper (DPC) structures 4 are respectively formed on the two printed copper layers 3. Each of the two direct plated copper (DPC) structures 4 includes a sputtered layer 41, a chemical plated copper layer 42, and an electroplated copper layer 43, the chemical plated copper layer 42 is arranged between the sputtered layer 41 and the electroplated copper layer 43, and the sputtered layer 41 is disposed adjacent to the ceramic substrate 1.

In each of the direct plated copper (DPC) structures 4, the sputtered layer 41 can include a sputtered titanium layer 411 and a sputtered copper layer 412, the sputtered titanium layer 411 is arranged adjacent to ceramic substrate 1, and the sputtered copper layer 412 is in contact with the chemical plated copper layer 42.

In each of the direct plated structures 4, a thickness of the electroplated copper layer 43 can be between 20 μm and 800 μm. Preferably, the thickness of the electroplated copper layer 43 can be between 50 μm and 250 μm. More preferably, the thickness of the electroplated copper layer 43 can be between 100 μm and 200 μm.

As shown in FIG. 1, in one embodiment, at least one of the direct plated copper (DPC) structures 4 only partially covers a corresponding one of the printed copper layers 3, and a surface of the corresponding one of the printed copper layers 3 away from the ceramic substrate 1 is partially exposed from the at least one of the direct plated copper (DPC) structures 4. More specifically, the direct plated copper (DPC) structure 4 can cover a central region of the printed copper layer 3, and a peripheral region of the printed copper layer 3 surrounding the central region is exposed from the direct plated copper (DPC) structure 4. In other words, in the present embodiment, a dimension of each of the direct plated copper (DPC) structures 4 along a horizontal direction is less than a dimension of the corresponding one of the printed copper layers 4 along the horizontal direction, but the present disclosure is not limited thereto. In addition, another one of the direct plated copper (DPC) structures 4 can only partially cover another one of the printed copper layers 3, but the present disclosure is not limited thereto.

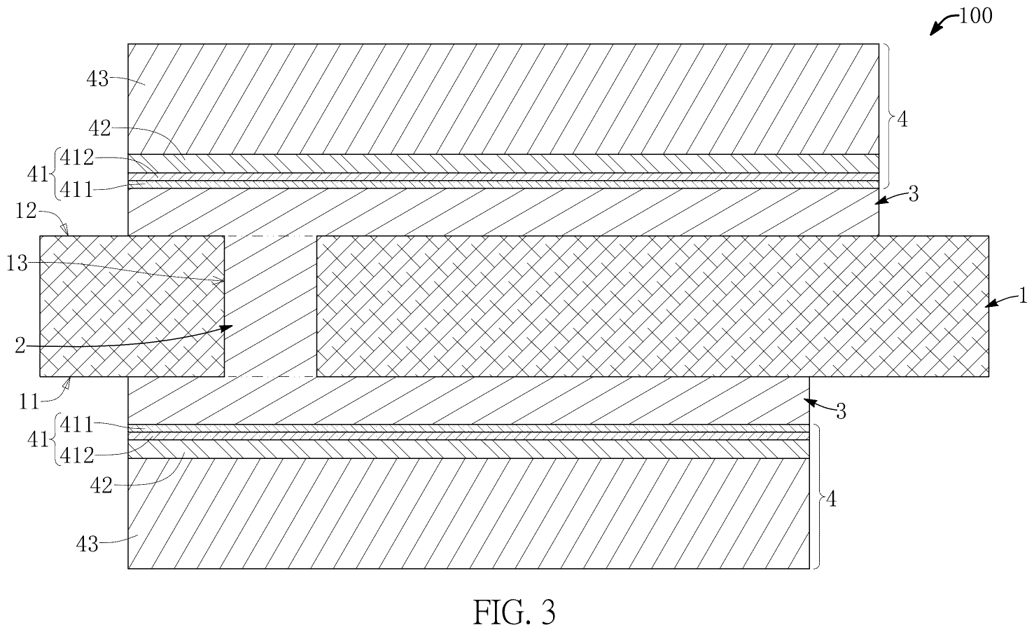

Referring to FIG. 3, FIG. 3 is a cross-sectional schematic view of two printed copper layers flush with two structures of the high reliability ceramic circuit board according to one embodiment of the present disclosure. In one embodiment, a plurality of side edges of at least one of the direct plated copper (DPC) structures 4 can be flush with a plurality of side edges of a corresponding one of the printed copper layers 3, and a plurality of side edges of another one of the direct plated copper (DPC) structures 4 can be flush with a plurality of side edges of another one of the printed copper layers 3, but the present disclosure is not limited thereto. More specifically, each of the direct plated copper (DPC) structures 4 can have four side edges, and the four side edges of the direct plated copper (DPC) structure 4 are flush with four side edges of the printed copper layer 3.

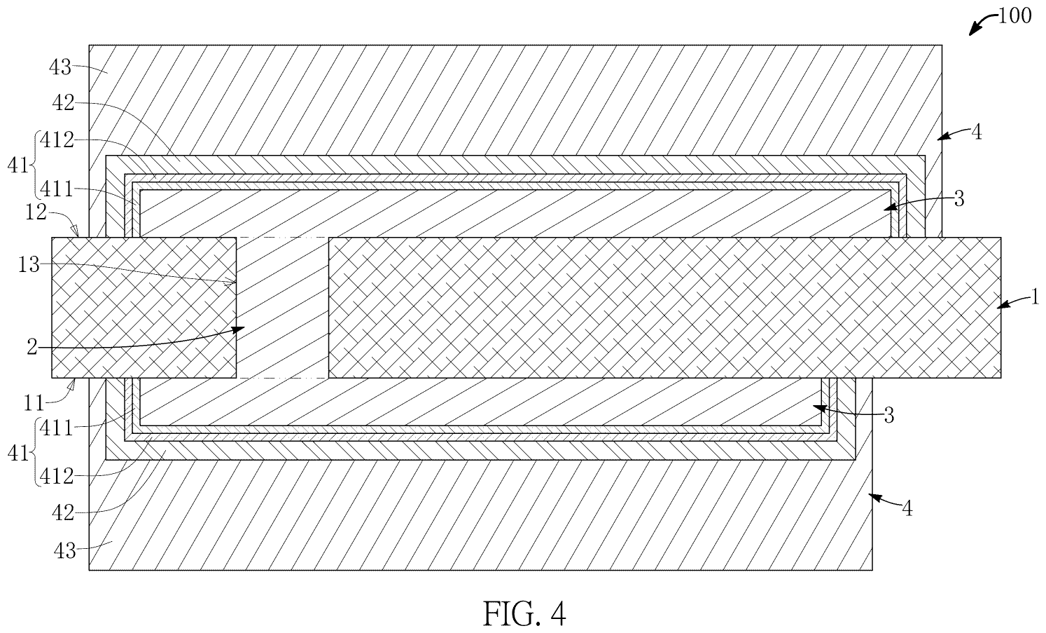

Referring to FIG. 4, FIG. 4 is a cross-sectional schematic view of the two printed copper layers protruding from the two direct plated copper (DPC) structures of the high reliability ceramic circuit board according to one embodiment of the present disclosure. In one embodiment, at least one of the direct plated copper (DPC) structures 4 covers the side edges of a corresponding one of the printed copper layers 3 and a surface of the corresponding one of the printed copper layers 3 away from the ceramic substrate 1, such that the side edges of the printed copper layer 3 and the surface of the printed copper layer 3 are not exposed from the direct plated copper (DPC) structure 4.

More specifically, in the direct plated copper (DPC) structure 4, the side edges of the sputtered layer 41, the side edges of the chemical plated copper layer 42, and the side edges of the electroplated copper layer 43 extend along a vertical direction toward the ceramic substrate 1, such that the direct plated copper (DPC) structure 4 shows multi-layer stacking in the horizontal direction. In addition, another one of the direct plated copper (DPC) structures 4 can cover the side edges of another one of the printed copper layers 3 and the surface of the another one of the printed copper layers 3, but the present disclosure is not limited thereto.

According to the above, the configuration of the direct plated copper (DPC) structure 4 and the printed copper layer 3 on the first surface 11 can be the same as or different from the configuration of the direct plated copper (DPC) structure 4 and the printed copper layer 3 on the second surface 12.

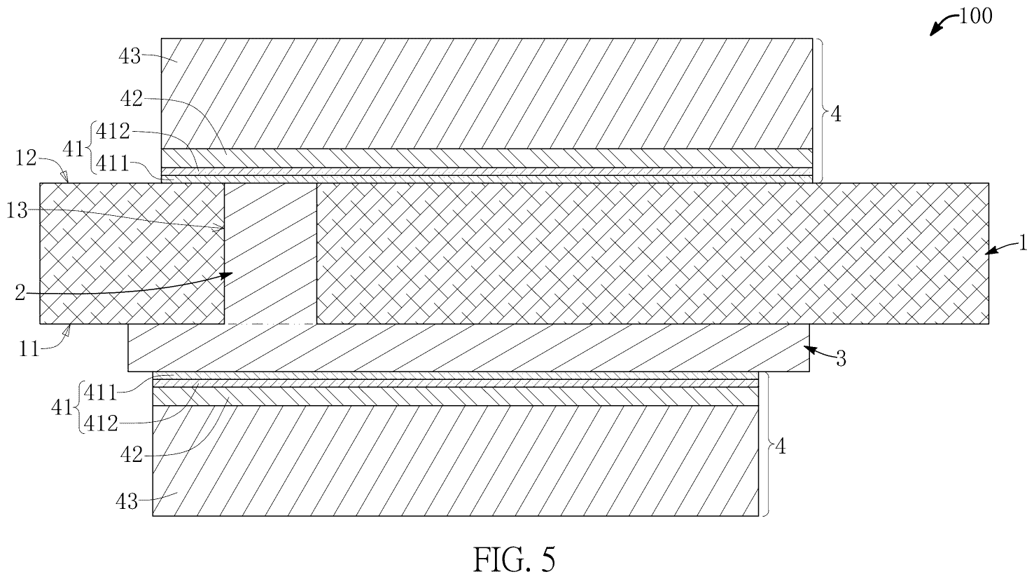

Referring to FIG. 5, FIG. 5 is a cross-sectional schematic view of the high reliability ceramic circuit board according to another embodiment of the present disclosure. The present embodiment provides a high reliability ceramic circuit board 100, the high reliability ceramic circuit board 100 in the present embodiment is similar to the high reliability ceramic circuit board 100 in the above-mentioned embodiment, and the differences are described as follows.

In the present embodiment, the quantity of the printed copper layer 3 included in the high reliability ceramic circuit board 100 is one, and the two direct plated copper (DPC) structures 4 are respectively formed on the printed copper layer 3 and the second surface 12 of the ceramic substrate 1. In other words, the second surface 12 can be provided without the printed copper layer 3 formed thereon, and the direct plated copper (DPC) structure 4 can be directly formed on the ceramic substrate 1 and directly in contact with the copper pillar structure 2. In the present embodiment, the printed copper layer 3 is formed on the first surface 11, and the first surface 11 is a lower surface (as shown in FIG. 5) of the ceramic substrate 1, but the present disclosure is not limited thereto. For example, in other embodiments, the first surface 11 and the second surface 12 can be an upper surface and the lower surface of the ceramic substrate 1, the printed copper layer 3 is formed on the first surface 11 (i.e., the printed copper layer 3 is formed on the upper surface of the ceramic substrate 1), and the lower surface (i.e., the second surface 12) of the ceramic substrate 1 does not have the printed copper layer 3 formed thereon.

### [Method for Producing a High Reliability Ceramic Circuit Board]

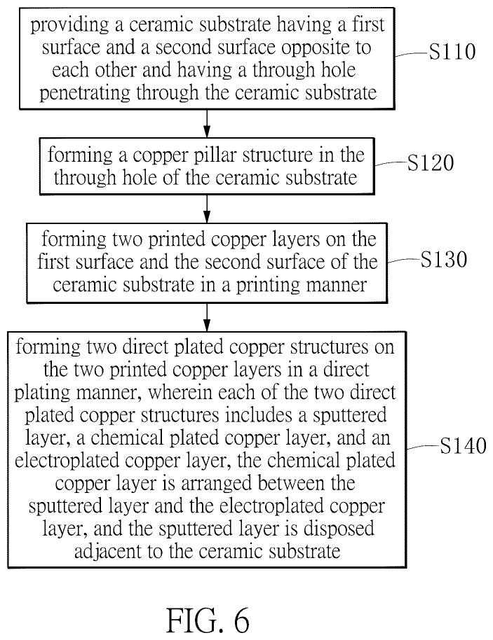

Referring to FIG. 6 to FIG. 9, FIG. 6 to FIG. 9 are flowcharts of a method for producing a high reliability ceramic circuit board according to different embodiments of the present disclosure. The present disclosure further provides a method for producing a high reliability ceramic circuit board. The above-mentioned high reliability circuit board 100 can be obtained by implementing the method for producing the high reliability ceramic circuit board, but the present disclosure is not limited thereto.

As shown in FIG. 6, the method for producing the high reliability ceramic circuit board includes a preparing process S110, a copper pillar structure forming process S120, a printing process S130, and a direct plating process S140. Naturally, the method for producing the high reliability ceramic circuit board can include other processes according to practical requirements, but the present disclosure is not limited thereto.

In the preparing process S110, a ceramic substrate 1 is provided, and the ceramic substrate 1 has a first surface 11 and a second surface 12 opposite to each other and has a through hole 13 penetrating through the ceramic substrate 1.

In the copper pillar structure forming process S120, a copper pillar structure 2 is formed in the through hole 13 of the ceramic substrate 1.

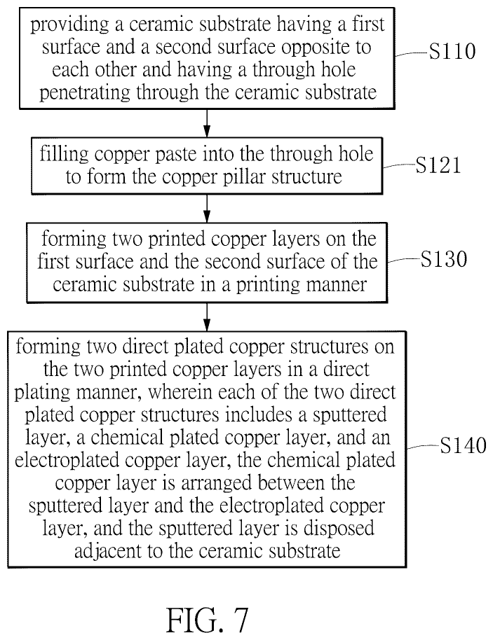

As shown in FIG. 7, in one embodiment, the copper pillar structure forming process S120 includes a copper filling process S121 implemented by filling copper paste into the through hole 13 to form the copper pillar structure 2.

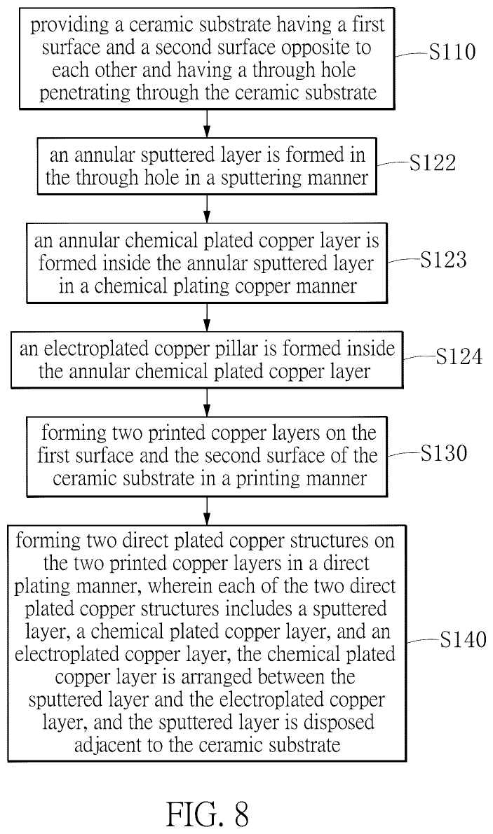

As shown in FIG. 8, in one embodiment, the copper pillar structure forming process S120 includes a through hole sputtering process S122, a through hole chemical plating copper process S123, and a through hole electroplating process S124. In the through hole sputtering process S122, an annular sputtered layer 21 is formed in the through hole 13 in a sputtering manner. In through hole chemical plating copper process S123, an annular chemical plated copper layer 22 is formed inside the annular sputtered layer 21 in a chemical plated copper manner. In the through hole electroplating process S124, an electroplated copper pillar 23 is formed inside the annular chemical plated copper layer 22. The copper pillar structure 2 can be a direct plated copper (DPC) pillar and includes the annular sputtered layer 21, the annular chemical plated copper layer 22, and the electroplated copper pillar 23. In addition, the annular sputtered layer 21 can further include an annular sputter titanium layer 211 and an annular sputtered copper layer 212, the annular sputtered titanium layer 211 is in contact with the hole wall of the through hole 13, and the annular sputtered copper 212 is arranged inside the annular sputtered titanium layer 211 and in contact with the annular chemical plated copper layer 22.

In the printing process S130, two printed copper layers 3 are formed on the first surface 11 and the second surface 12 of the ceramic substrate 1 in a printing manner. A thickness of each of the printed copper layer 3 is less than 15 μm.

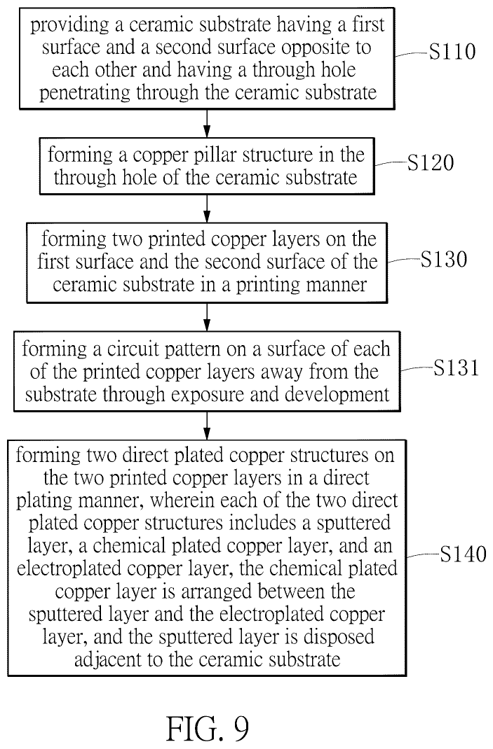

As shown in FIG. 9, after the printing process S130 and before the direct plating process S140, the method further includes a circuit pattern forming process S131 implemented by forming a circuit pattern on a surface of each of the printed copper layers 3 away from the substrate 1 through exposure and development.

It is worth mentioning that, in a general direct bonded copper (i.e., DBC) procedure, after a copper foil layer is covered on a ceramic substrate, a circuit pattern is carved on the ceramic substrate through exposure, development and etching, and a precision of the circuit pattern formed through direct bonded copper procedure is relatively low. In contrast, in the method of the present embodiment, through the circuit pattern forming process S131 implemented before the direct plating process S140, a relatively precise circuit pattern is formed. In addition, after the direct plating process S140, the method can be provided without including other circuit forming processes, but the present disclosure is not limited thereto.

In the direct plating process S140, two direct plated copper (DPC) structures 3 are formed on the two printed copper layers 3 in a direct plating manner. Each of the two direct plated copper (DPC) structures 4 includes a sputtered layer 41, a chemical plated copper layer 42, and an electroplated copper layer 43, the chemical plated copper layer 42 is arranged between the sputtered layer 41 and the electroplated copper layer 43, and the sputtered layer 41 is disposed adjacent to the ceramic substrate 1. In each of the direct plated copper (DPC) structures 4, the sputtered layer 41 can include a sputtered titanium layer 411 and a sputtered copper layer 412, the sputtered titanium layer 411 is arranged adjacent to ceramic substrate 1, and the sputtered copper layer 412 is in contact with the chemical plated copper layer 42.

### Beneficial Effects of the Embodiment

In conclusion, in the high reliability ceramic circuit board and method for producing the same provided by the present disclosure, by virtue of “the direct plated copper (DPC) structure being formed on the printed copper layer” and “the direct plated copper (DPC) structure including the sputtered layer, the chemical plated copper layer, and the electroplated copper layer,” a conventional ceramic circuit board that can be easily cracked after undergoing several times of temperature cycling tests is improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A high reliability ceramic circuit board, comprising:
a ceramic substrate having a first surface and a second surface opposite to each other and having a through hole penetrating through the ceramic substrate;
a copper pillar structure formed in the through hole of the ceramic substrate;
two printed copper layers respectively formed on the first surface and the second surface, wherein the two printed copper layers are in contact with the copper pillar structure; and
two direct plated copper (DPC) structures respectively formed on the two printed copper layers, wherein each of the two direct plated copper (DPC) structures includes a sputtered layer, a chemical plated copper layer, and an electroplated copper layer, the chemical plated copper is arranged between the sputtered layer and the electroplated copper layer, and the sputtered layer is disposed adjacent to the ceramic substrate.

2. The high reliability ceramic circuit board according to claim 1, wherein the copper pillar structure is a direct plated copper (DPC) pillar, the copper pillar structure includes an annular sputtered layer in contact with a hole wall of the through hole, an annular chemical plated copper layer arranged inside the annular sputtered layer, and an electroplated copper pillar arranged inside the annular chemical plated copper layer.

3. The high reliability ceramic circuit board according to claim 1, wherein a thickness of each of the printed copper layers is less than 15 μm.

4. The high reliability ceramic circuit board according to claim 1, wherein, in each of the direct plated copper (DPC) structures, the sputtered layer includes sputtered titanium layer and a sputtered copper layer, the sputtered titanium layer is disposed adjacent to the ceramic substrate, and the sputtered copper layer is in contact with the chemical plated copper layer.

5. The high reliability ceramic circuit board according to claim 1, wherein, in each of the direct plated copper (DPC) structures, a thickness of the electroplated copper layer is between 20 μm and 800 μm.

6. The high reliability ceramic circuit board according to claim 1, wherein a plurality of side edges of at least one of the direct plated copper (DPC) structures are flush with a plurality of side edges of a corresponding one of the printed copper layers.

7. The high reliability ceramic circuit board according to claim 1, wherein at least one of the direct plated copper (DPC) structures only partially covers a corresponding one of the printed copper layers, and a surface of the corresponding one of the printed copper layers away from the ceramic substrate is partially exposed from the at least one of the direct plated copper (DPC) structures.

8. The high reliability ceramic circuit board according to claim 1, wherein at least one of the direct plated copper (DPC) structures covers a plurality of side edges of a corresponding one of the printed copper layers and a surface of the corresponding one of the printed copper layers away from the ceramic substrate.

9. A high reliability ceramic circuit board, comprising:
a ceramic substrate having a first surface and a second surface opposite to each other and having a through hole penetrating through the ceramic substrate;
a copper pillar structure formed in the through hole of the ceramic substrate;
a printed copper layer formed on the first surface and in contact with the copper pillar structure; and
two direct plated copper (DPC) structures respectively formed on the printed copper layer and the second surface of the ceramic substrate, wherein each of the two direct plated copper (DPC) structures includes a sputtered layer, a chemical plated copper layer, and an electroplated copper layer, the chemical plated copper layer is arranged between the sputtered layer and the electroplated copper layer, and the sputtered layer is disposed adjacent to the ceramic substrate.

10. A method for producing a high reliability ceramic circuit board, comprising:
a preparing process implemented by providing a ceramic substrate having a first surface and a second surface opposite to each other and having a through hole penetrating through the ceramic substrate;
a copper pillar structure forming process implemented by forming a copper pillar structure in the through hole of the ceramic substrate;
a printing process implemented by forming two printed copper layers on the first surface and the second surface of the ceramic substrate in a printing manner; and
a direct plating process implemented by forming two direct plated copper (DPC) structures on the two printed copper layers in a direct plating manner, wherein each of the two direct plated copper (DPC) structures includes a sputtered layer, a chemical plated copper layer, and an electroplated copper layer, the chemical plated copper layer is arranged between the sputtered layer and the electroplated copper layer, and the sputtered layer is disposed adjacent to the ceramic substrate.

11. The method according to claim 10, wherein the copper pillar structure forming process includes a copper filling process implemented by filling copper paste into the through hole to form the copper pillar structure.

12. The method according to claim 10, wherein the copper pillar structure forming process includes a through hole sputtering process, a through hole chemical plating copper process, and a through hole electroplating process; wherein, in the through hole sputtering process, an annular sputtered layer is formed in the through hole in a sputtering manner, in the through hole chemical plating copper process, an annular chemical plated copper layer is formed inside the annular sputtered layer in a chemical plating copper manner, and in the through hole electroplating process, an electroplated copper pillar is formed inside the annular chemical plated copper layer; and wherein the copper pillar structure is a direct plated copper (DPC) pillar and includes the annular sputtered layer, the annular chemical plated copper layer, and the electroplated copper pillar.

13. The method according to claim 10, wherein a thickness of each of the printed copper layers is less than 15 um.

14. The method according to claim 10, wherein, after the printing process and before the direct plating process, the method further includes a circuit pattern forming process implemented by forming a circuit pattern on a surface of each of the printed copper layers away from the substrate through exposure and development.

15. The method according to claim 10, wherein, in each of the direct plated copper (DPC) structures, the sputtered layer includes sputtered titanium layer and a sputtered copper layer, the sputtered titanium layer is disposed adjacent to the ceramic substrate, and the sputtered copper layer is in contact with the chemical plated copper layer.
